(19) United States
(12) Patent Application Publication
(10) Pub. No.: US 2003/0047283 A1
(43) Pub. Date: Mar. 13, 2003

(54) Apparatus for supporting a substrate and method of fabricating same

(75) Inventors: Vijay D. Parkhe, San Jose, CA (US); Chandra V. Deshpandey, Fremont, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 09/953,654

(22) Filed: Sep. 10, 2001

(51) Int. Cl. C23C 16/00; C23F 1/02

(52) U.S. Cl. 156/345.51; 118/728

(57) ABSTRACT

Apparatus for supporting a substrate comprising a chuck body and a carbon-based surface treatment, deposited or otherwise created upon the support surface. The chuck body comprises a material selected from the group of zirconium, zirconium alloys, and metal/ceramic composites. The protective surface treatment may also contain silicon-based materials. The protective surface treatment is preferably about one to about five microns thick and has a coefficient of thermal expansion in the range of about 3 ppm per Celsius degree to about 6 ppm per Celsius degree. A concomitant method of fabricating a substrate support chuck comprises the steps of forming a chuck body having a support surface and depositing a carbon-based material on the support surface of the chuck body to form a protective surface treatment. The chuck body comprises a material selected from the group of zirconium, zirconium alloys, and metal/ceramic composites.

### BACKGROUND OF THE INVENTION

1. Field of the Invention

The invention relates to an apparatus for supporting a semiconductor wafer within a semiconductor processing system. More particularly, the invention relates to an electrostatic chuck containing a protective coating and chuck body and a method of fabricating same.

2. Description of the Background Art

The construction of semiconductor devices requires numerous processing steps in order to produce an integrated circuit with desired properties. Conventional semiconductor processing tools employ a support structure to retain a wafer or other workpiece upon which devices are constructed throughout these processing steps. The support structure that is utilized is an electrostatic chuck that is designed to retain the wafer by electrostatic attraction between the wafer and the chuck. A wafer that is electrostatically retained is then available to undergo the required processing steps to create the highly defined features of an integrated circuit.

Although various electrostatic chuck designs have been fabricated and discussed in the art, typical electrostatic chucks are comprised of one or more dielectric materials (insulators) surrounding conductive materials (electrodes). The chuck is electrically biased using a high voltage DC or RF source. In either case, a potential difference develops between the chuck and the wafer, causing the wafer to be held in place.

One type of electrostatic chuck consists of ceramic chuck body in which conductive electrodes are embedded. Common ceramic materials used for the chuck body include aluminum oxide and aluminum nitride. Such ceramic materials are selected on the basis of their mechanical durability, dielectric properties, thermal properties, and ease of processing.

Chucks having bodies fabricated from metallic materials such as stainless steel and aluminum are significantly less expensive to fabricate than chucks fabricated from ceramic. Metallic chucks are therefore used in numerous applications of semiconductor processing including physical vapor deposition (PVD) and ion metal plasma (IMP) chambers and various other reactors. Metallic chuck bodies must typically be coated with a dielectric material in order to develop a sufficient electrostatic field to hold a wafer in place. Typical coating materials include aluminum oxide and boron nitride among others.

Such typical dielectric coatings have a thermal expansion coefficient that differs significantly from either the ceramic or metallic chuck body materials. As a result, the coating integrity is compromised when the system is subject to numerous cycles of alternating heating and cooling (expansion and contraction of the different materials) that occur during the operation of the chuck. The coating is then subject to premature failure through flaking, cracking and the like. Therefore, a need exists for a substrate support and coating of suitably compatible materials to prevent or avoid particle generation and/or coating support material failures as well as a method for fabricating same.

### SUMMARY OF THE INVENTION

The disadvantages associated with prior art are overcome by the present invention of an apparatus for supporting a substrate comprising a support surface consisting of a chuck body and a surface treatment, deposited or otherwise disposed upon the support surface. The chuck body comprises a material selected from the group of zirconium, zirconium alloys, metal/ceramic composites, and combinations thereof. The surface treatment is carbon-based and may further comprise silicon-based materials, for example a material comprising carbon, oxygen, silicon, and hydrogen. Alternatively, the surface treatment may be further comprised of other materials in addition to or in place of the previously mentioned materials. These additional materials include tantalum-based materials, boron-based materials, and nitrogen-based materials. The surface treatment is approximately 1 to 5 microns thick and has a thermal expansion coefficient between about 3 and about 6 ppm per Celsius degree.

A method of fabricating a substrate support chuck is also disclosed and comprises the steps of forming a chuck body having a support surface and disposing a carbon-based material on the support surface of said chuck body to form a protective surface treatment. The chuck body is selected from the group consisting of zirconium, zirconium alloys, metal/ceramic composites, and combinations thereof. Optionally, the step of providing a plurality of channels into the protective surface treatment is added. Furthermore, a thermal choke device and bottom plate are provided.

### BRIEF DESCRIPTION OF THE DRAWINGS

The teachings of the present invention can be readily understood by considering the following detailed description in conjunction with the accompanying drawing, in which:

FIG. 1a depicts a vertical cross-sectional view of a zirconium-based electrostatic chuck containing a protective surface treatment in accordance with the present invention;

FIG. 1b depicts a vertical cross-sectional view of a electrostatic chuck with a metal/ceramic composite chuck body and containing a protective surface treatment in accordance with the present invention.

FIG. 2 depicts a vertical cross-sectional view of an additional embodiment of the subject invention having the protective surface treatment fabricated as to accept a thermal transfer medium;

FIG. 3 depicts a series of method steps for making the electrostatic chuck having the protective surface treatment; and

FIG. 4 depicts a vertical cross-sectional view of a third embodiment of the subject invention having the protective surface treatment as well as a thermal choke and bottom plate.

### DETAILED DESCRIPTION OF THE INVENTION

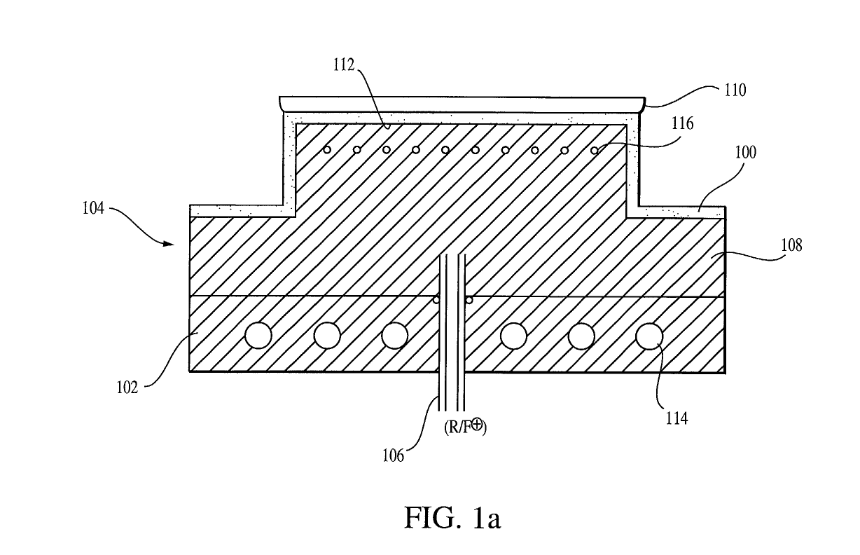

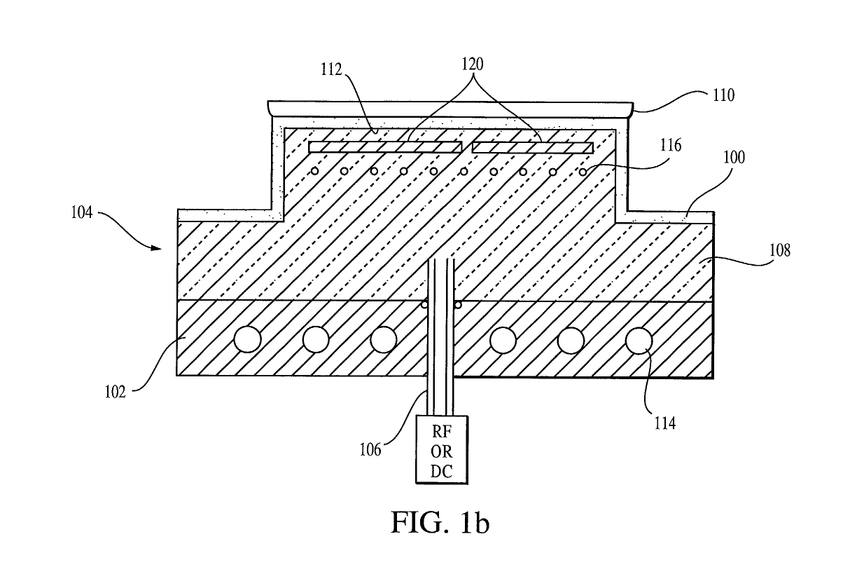

FIG. 1a depicts a cross-sectional view of an electrostatic chuck 104 in accordance with the present invention. Such an electrostatic chuck 104 is used to retain and support a substrate, such as a semiconductor wafer 110, in a process chamber (not shown). Process chambers perform a variety of process steps upon the substrate (e.g., deposition by physical or chemical vapor means, etching, polishing and the like) to fabricate integrated circuits thereupon. Specifically, the chuck 104 has a body 108 consisting of a zirconium-based material and protective surface treatment 100 disposed thereover. The protective surface treatment 100 comprises a carbon-based material and may further comprise one or more materials selected from the following group: a silicon-based material, a tantalum-based material, a boron-based material, a nitrogen-based material, and combinations thereof. The term “protective surface treatment” is defined to be a layer of material that has a composition that is purposefully made distinct from the material which it underlies. This is accomplished by disposing a coating of material over the chuck body 108 by various chemical or physical vapor deposition processes known to those skilled in the art. The chuck 104 is disposed upon a pedestal base 102.

The chuck 104 depicted in FIG. 1a is a monopolar configuration. A voltage is applied to the chuck body 108, using an RF or DC source 106, relative to some internal chamber ground reference (e.g., chamber wall not shown). The wafer 110 is retained by coulomb force. That is, charges accumulate on the underside of the wafer 110 and a support surface 112 covered by the coating 100 while a plasma (not shown) generated proximate the chuck supplies a conductive path from the wafer 110 to ground. Although a monopolar configuration is described, this does not preclude other types of configurations and is bipolar, tripolar and the like. An exemplary bipolar chuck configuration that can be adapted for use in the subject invention is seen and described in U.S. Pat. No. 5,656,093, issued Aug. 12, 1997 to Burkhart et al. and commonly assigned to the assignee of the subject application, Applied Materials, Inc. of Santa Clara, Calif. This reference discloses a bipolar electrostatic chuck configuration having DC biasing of the chucking electrodes. RF power can be superimposed upon the DC to provide negative bias to the wafer for plasma processing. Additionally, channels 114 are provided in the pedestal base 102. The channels 114 allow for cooling fluid such as water, to flow through the pedestal base 102 thereby regulating chuck body and pedestal base temperature. A heater coil 116 may also be provided in the chuck body 108. The heater coil also regulates chuck body temperature as required. It will be understood that the channels 114 and heater coil 116 are provided with the necessary facilities connections (i.e. facilities water and electrical power respectively) though not specifically depicted. Other embodiments of the subject invention discussed below and depicted elsewhere may also have these temperature control features though not specifically shown or discussed further.

In an alternate embodiment depicted in FIG. 1b, the chuck body 108 comprises a metal/ceramic composite material. The metal/ceramic composite comprises a metallic component and a ceramic component. The metallic component comprises for example, aluminum. The metallic component further comprises silicon. The ceramic component comprises, for example, silicon carbide. The chuck depicted in FIG. 1b further comprises one or more electrodes 120 typically constructed from a conductive material, such as, for example, titanium or copper. In a preferred embodiment, the chuck body 108 comprises silicon carbide and an alloy of aluminum and silicon. Electrodes 120 provide a chucking force to hold substrate 110 in place on the chuck 104. The protective surface treatment 100 is composed of one or more constituents including the following: a carbon-based material, a silicon-based material, a tantalum-based material, a boron-based material, and a nitrogen-based material.

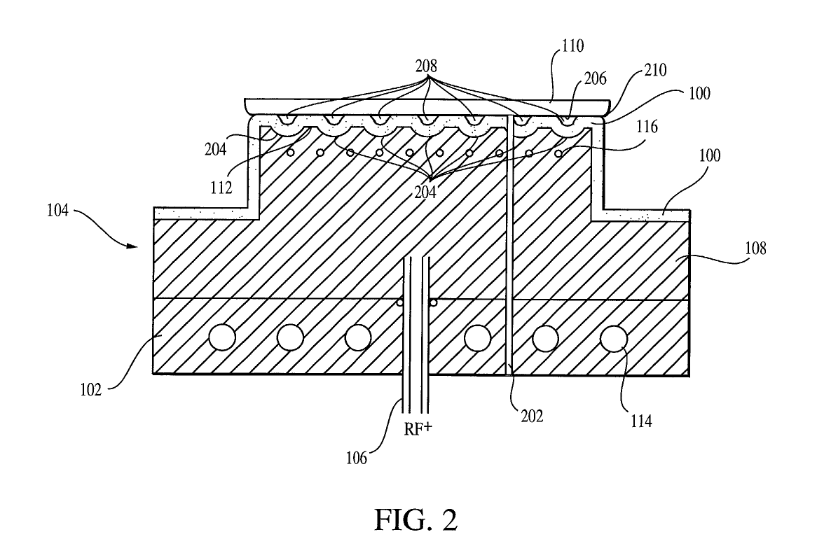

In another alternate embodiment of the invention depicted in FIG. 2, an additional feature is added to the electrostatic chuck 104. A port 202 is formed through the chuck body 108 to a top surface 210 of the coating 100. An inert gas such as helium flows through the port 202 from a remote source (not shown). The inert gas improves the rate of heat transfer from the wafer 110 to the chuck 104, thus providing thermal uniformity to the wafer 110 during processing. The medium is usually supplied to a back surface 206 of the wafer 110 at a rate of approximately 2 to 30 sccm. Such backside cooling is well known in the art and is disclosed, for example, in commonly assigned U.S. Pat. No. 5,228,501 issued to Tepman, et al., on Jul. 20, 1993.

Specifically, a plurality of heat transfer medium distribution channels 204 are cut into the support surface 112. The protective surface treatment 100 conformally coats the support surface 112 to yield a plurality of conformal channels 208 in the protective surface treatment 100.

Prior to applying the protective surface treatment 100, the chuck 104 is cleaned by either a plasma or sputter etch process. Then, the protective surface treatment 100 is deposited upon the support surface 112 of the chuck body 108 typically by plasma-enhanced chemical vapor deposition (CVD) of a carbon-based nano-composite further comprising a silicon-based material. A thermal CVD process may also be performed in lieu of the plasma-enhanced process. The protective surface treatment 100 structure has high mechanical strength and resistance to chemical and electrical breakdown. The optional silicon-based material provides the protective surface treatment with a more stable resistivity throughout the operational temperature range of the chuck 104 (typically from room temperature to about 550° C.). The optional tantalum-based material, the optional boron-based material, and the optional nitrogen-based material further serve to provide improved mechanical durability and improved thermal expansion characteristics. Regardless of the specific composition of the protective surface treatment 100, the coefficient of thermal expansion of the treatment is approximate to that of the chuck 104. Preferably, the coefficient of thermal expansion is in the range of approximately 3-6 ppm per Celsius degree.

An example of a suitable surface treatment is a silicon-carbon composite material having the brand name DLN. DLN is manufactured and sold by Advanced Refractory Technologies, Inc. of Buffalo, N.Y. The protective coating 100 is evenly and conformally deposited across the entire support surface 112 of the chuck body 108 in the embodiments shown in FIGS. 1 and 2. Other deposition techniques include sputtering, flame spraying and the like. The material of the protective coating has a superior non-reactive property as compared to the support surface material of the chuck. This material prevents adsorption or reaction of the support surface 112 with contaminants in the atmosphere and is stable in a vacuum environment such as in a process chamber in which the electrostatic chuck 104 is used. Other types of materials may also comprise the protective surface treatment 100 and may be selected from the group consisting of boron nitride, tantalum pentoxide, and aluminum nitride.

When the protective surface treatment 100 is deposited as a thin layer using the above-mentioned materials, it will have a thickness of, for example, approximately 1-5 μm. Such material, when thinly deposited does not require lapping nor sintering and, as such, is not fractured or porous. Additionally, a surface created by such coating does not react with hydrocarbons and other such contaminants. The thickness of the protective surface treatment 100 does not interfere or severely reduce the chucking force and facilitates conformal coating over the channels 204 in the support surface 112. Typically, the resistivity of the surface treatment is approximately 10⁹-10¹⁵ ohm centimeters to create the desired results. This value can be altered as necessary by a separate conductive material sputtering or doping step. That is, a conductive material (i.e., aluminum or titanium) is sputtered into the protective coating 100 to dope the coating or otherwise alter its resistivity.

It should be noted that the dimensions of the protective surface treatment 100 and channels 204 have been greatly exaggerated for easy viewing and understanding of the invention. Typically, the channels 120 formed in the chuck body 108 are approximately 50 μm deep. As discussed, the protective surface treatment 100 has a thickness up to about 5 microns.

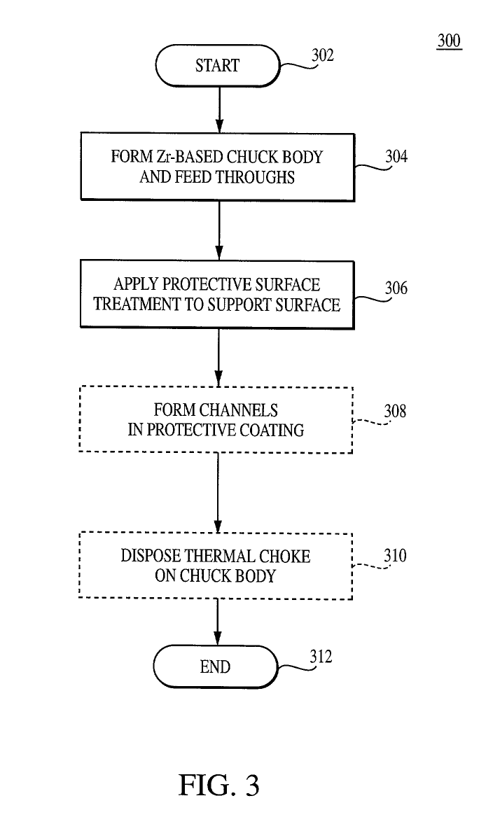

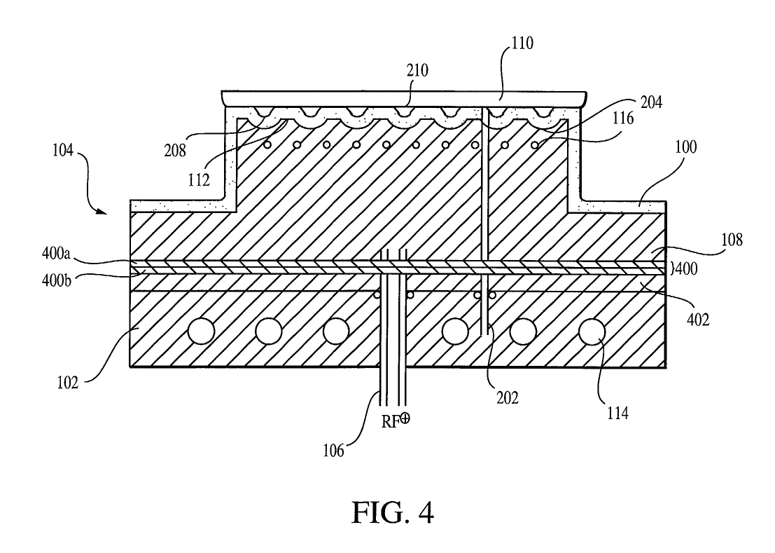

A method for forming the electrostatic chuck 104 is depicted in FIG. 3. Specifically, a series of method steps 300 begins at step 302 and proceeds to step 304 wherein the electrostatic chuck body 108 is formed from a zirconium-based material with appropriate bores provided for electrical feed-throughs (wires). At step 306, a protective surface treatment is deposited upon the chuck body. The protective treatment 100 is fabricated from carbon-based materials. Optionally, and as shown in step 310, a thermal choke is disposed on the chuck body. The details of the thermal choke are described below with respect to FIG. 4. The method ends at step 312. Optionally, and as part of an alternate method of making the electrostatic chuck 104 (the alternate embodiment of FIG. 2) at step 308, channels are fabricated into the support surface 112. The channels facilitate the flowing of gas that facilitates thermal transfer between the treatment and wafer. The protective surface treatment of the current invention is applied by any of the known methods of those skilled in the art of substrate support fabrication and include but are not limited to chemical vapor deposition or the like. A preferred thickness for the coating is between 1 and 5 microns. The preferred resistivity of the coating is between 10⁹ and 10¹⁵ ohm centimeters. The method ends at step 312 wherein a completely formed electrostatic chuck having a protective coating is now available for use (assembly into a process chamber).

In a second alternate embodiment of the invention depicted in FIG. 4, an additional feature is added to the electrostatic chuck 104. The chuck 104 is provided with a thermal choke 400 and a bottom plate 402. Specifically, the thermal choke 400 is disposed directly below and in contact with the chuck body 108. The thermal choke 400 comprises a thermally insulating layer 400a. The thermally insulating layer 400a may be constructed of a material such as, for example, quartz. Disposed below the thermally insulating layer 400a is a heat reflective layer 400b. The heat reflective layer reflects heat that is generated below the thermal choke, thereby preventing the transfer of heat to components disposed above the thermal choke. The heat reflective layer 400b may be a thin metallic layer, for example, a metallic foil. The heat reflective layer 400b may comprise, for example, nickel. The thermal choke 400 allows the chuck to operate at high temperatures (500 C. or greater) yet allow components below the chuck to not be affected by these temperatures. Further, the chuck 104 can be detached from the pedestal base 102 for safe and convenient removal as well as replacement. Detachability of the chuck is achieved by many means known to those skilled in the art including bolts, clamp rings or the like.

In accordance with the disclosure provided, the subject invention is an electrostatic chuck body constructed of material consisting predominantly of zirconium or a metal/ceramic composite. Such a chuck body will have a relatively low fabrication cost compared to typical electrostatic chucks consisting of purely ceramic materials. The protective surface treatment 100 is fabricated from a material that has a coefficient of thermal expansion that is similar to the chuck body. This matching of thermal expansion coefficients greatly reduces or eliminates thermal stresses at the chuck body-surface treatment interface and the resulting premature failure of the electrostatic chuck. The protective coating reduces the likelihood of reaction with or formation of contaminants. The support surface 112 of the chuck 104 is sealed from a usually harsh process chamber environment. Additionally, the support surface 112 of the chuck 104 does not contact the backside 206 of the wafer 110.

Using the chuck body material in conjunction with the protective coating of the present invention results in a substantial decrease in contamination of chucks, wafers and the process chamber environment. The protective coating provides a durable protective barrier that is resistant to cracking, chipping, and flaking when subjected to thermal cycling during operation. Naturally occurring contaminants that would form a conductive film are substantially reduced. As such, the need to clean the support surface (i.e., by a sputter etch conditioning or similar maintenance step) is eliminated. Thus, downtime associated with reconditioning a poorly performing chuck is substantially reduced. Furthermore, the materials utilized in this invention allow for the fabrication of an electrostatic chuck that is, in some cases, significantly less expensive than those based upon conventional ceramic chuck bodies.

Although various embodiments which incorporate the teachings of the present invention have been shown and described in detail herein, those skilled in the art can readily devise many other varied embodiments that still incorporate these teachings.

What is claimed is:

1. Apparatus for supporting a substrate comprising:
a chuck body having a support surface, wherein the chuck body comprises a material selected from the group of materials consisting of zirconium, zirconium alloys, and metal/ceramic composites; and
a carbon-based surface treatment, disposed on the support surface;.

2. The apparatus of claim 1 wherein the chuck body further comprises silicon carbide.

3. The apparatus of claim 1 wherein the chuck body further comprises aluminum and silicon.

4. The apparatus of claim 1 wherein said surface treatment further comprises a material selected from the group consisting of silicon based materials, diamond-like nanocomposites, tantalum-based materials, and boron-based materials.

5. The apparatus of claim 1 wherein said surface treatment is a silicon oxicarbohydride.

6. The apparatus of claim 1 wherein the surface treatment is deposited via plasma-enhanced CVD.

7. The apparatus of claim 1 wherein the surface treatment is subsequently treated with a conductive material.

8. The apparatus of claim 7 wherein the conductive material is applied to the surface treatment via sputtering OR CVD.

9. The apparatus of claim 1 further comprising a thermal choke disposed below said chuck body.

10. The apparatus of claim 9 wherein the thermal choke comprises a thermal insulating material and a heat reflector material.

11. The apparatus of claim 10 wherein the thermally insulating material comprises silicon and oxygen.

12. The apparatus of claim 10 wherein the heat reflector material comprises a metal.

13. The apparatus of claim 12 wherein the heat reflector material comprises nickel.

14. The apparatus of claim 1 wherein the surface treatment is in the range of about 1 to about 5 microns (μm) thick.

15. The apparatus of claim 1 wherein the surface treatment has a coefficient of thermal expansion in the range of about 3 to about 6 ppm per Celsius degree.

16. The apparatus of claim 1 wherein the surface treatment has a resistivity in the range of 10⁹ to 10¹⁵ ohm centimeters.

17. The apparatus of claim 1 further comprising fluid cooling channels disposed below the support surface.

18. The apparatus of claim 1 wherein said apparatus is an electrostatic chuck.

19. The apparatus of claim 18 wherein the electrostatic chuck is selected from the group consisting of a monopolar configuration and a bipolar configutration.

20. A method of fabricating a substrate support chuck comprising the steps of:
forming a chuck having a support surface, wherein the chuck body is selected from the group of materials consisting of zirconium, zirconium alloys, and metal/ceramic composites; and
depositing a material on the support surface of said chuck body to form a protective surface treatment.

21. The method of claim 20 wherein the chuck body further comprises silicon carbide.

22. The method of claim 20 wherein the chuck body further comprises aluminum and silicon.

23. The method of claim 20 wherein said surface treatment further comprises a material selected from the group consisting of silicon based materials, diamond-like nanocomposites, tantalum-based materials, and boron-based materials.

24. The method of claim 20 wherein said surface treatment is a silicon oxicarbohydride.

25. The method of claim 20 wherein the surface treatment is deposited via plasma-enhanced CVD.

26. The method of claim 20 wherein the surface treatment is subsequently treated with a conductive material.

27. The method of claim 26 wherein the conductive material is applied to the surface treatment via sputtering.

28. The method of claim 20 further comprising forming a thermal choke on the chuck body.

29. The method of claim 28 wherein the thermal choke comprises a thermal insulating material and a heat reflector material.

30. The method of claim 29 wherein the thermally insulating material comprises silicon and oxygen.

31. The method of claim 29 wherein the heat reflector material comprises a metal.

32. The method of claim 31 wherein the heat reflector material comprises nickel.

33. The method of claim 20 wherein the surface treatment is deposited to a thickness in the range of about 1 to about 5 microns (μm) thick.

34. The method of claim 20 wherein the surface treatment has a coefficient of thermal expansion in the range of about 3 to about 6 ppm per Celsius degree.

35. The method of claim 20 wherein the surface treatment has a resistivity in the range of 10⁹ to 10¹⁵ ohm centimeters.
